(19) United States
(12) Patent Application Publication
(10) Pub. No.: US 2006/0072638 A1
(43) Pub. Date: Apr. 6, 2006

(54) External cavity type tunable laser source

(75) Inventor: Yasuhiro Tanaka, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: YOKOGAWA ELECTRIC CORPORATION

(21) Appl. No.: 11/227,140

(22) Filed: Sep. 16, 2005

(30) Foreign Application Priority Data
Sep. 17, 2004 (JP) P.2004-270897

(51) Int. Cl. H01S 3/00; H01S 5/00

(52) U.S. Cl. 372/38.02; 372/43.01

(57) ABSTRACT

An external cavity type tunable laser source has a laser diode which cooperates with a reflecting section to constitute an external cavity, and outputs laser light, a laser driving circuit which supplies a laser driving current to the laser diode, a random noise generator which generates a noise current whose current value varies at random, an amplitude control section which controls an amplitude of the noise current output from the random noise generator based on a light intensity of the laser light output from the laser diode, and a current superimposition section which superimposes a noise current whose amplitude is controlled by the amplitude control section on the driving current output from the laser driving circuit.

### CROSS-REFERENCE TO RELATED APPLICATIONS

This application is based upon and claims the benefit of priority from the prior Japanese Patent Applications No. 2004-270897, filed on Sep. 17, 2004, the entire contents of which are incorporated herein by reference.

### BACKGROUND OF THE INVENTION

1. Field of the Invention

The invention relates to an external cavity type tunable laser source having a laser diode which cooperates with a reflecting section to constitute an external cavity and outputs laser light, a laser driving circuit which supplies a laser driving current to the laser diode, and a random noise generator which superimposes a noise current whose current value varies at random on the driving current output from the laser driving circuit. The invention particularly relates to an external cavity type tunable laser source in which optical modulation can be performed irrespective of the optical power.

2. Description of the Related Art

An external cavity type tunable laser source can vary the wavelength over a wide range. In some of such external cavity type tunable laser sources, the spectral line width is 500 [kHz] or less at full width half maximum, or namely the spectral line width is narrow, and therefore the coherence is very excellent.

In an actual measurement (for example, when an optical power (also, called a light intensity) is measured by an optical power meter), however, the excellent coherence allows interference noises to be generated, thereby causing a measurement error. Usually, there is a reflection point in a measurement system, and interference occurs between measurement light and reflected light. The optical path difference between measurement light and reflected light is often varied during measurement, and interference noises are generated to cause a light intensity of measurement light to be varied.

As a method of performing optical modulation to widen the spectral line width and reduce interference noises, what is proposed are a configuration in which the length of an external cavity is varied (For example, see Japanese Patent No. 3,422,804.), and that in which random noises are superimposed on a laser driving current for driving a laser diode (For example, see JP-A-10-107354.).

FIG. 4 is a diagram showing the configuration of an external cavity type tunable laser source as a related art (random noises are superimposed on a laser driving current) (For example, see JP-A-10-107354.). With reference to FIG. 4, an external cavity type tunable laser source in a Littman arrangement will be described as an example. An optical amplifier 10 has a laser diode 11, a first lens 12, and a second lens 13. The laser diode 11 has an antireflection coating 11a at one end. The first lens 12 converts light emitted from the one end (the end face where the antireflection coating 11a is formed) of the laser diode 11 to collimating beam, and emits the collimating beam. The second lens 13 converts light emitted from the other end of the laser diode 11 to collimating beam and emits the collimating beam.

A wavelength selecting section 20 has a diffraction grating 21, a wavelength selecting mirror 22, and mirror rotating section 23, selects the wavelength of the laser beam emitted from the one end of the optical amplifier 10, and feedbacks the selected light to the optical amplifier 10. The diffraction grating 21 wavelength-disperses the light from the optical amplifier 10 and that from the wavelength selecting mirror 22. The wavelength selecting mirror 22 reflects the light wavelength-dispersed by the diffraction grating 21, to the diffraction grating 21. The mirror rotating section 23 rotates the wavelength selecting mirror 22 to select the wavelength of the light which is to be fed back by the diffraction grating 21 to the optical amplifier 10.

A laser driving circuit 30 outputs a laser driving current for driving the laser diode 11. A random noise generator 40 amplifies white noises such as thermal noises and shot noises, for example, noises generated by a Zener diode or the like, to a current of a predetermined amplitude, and outputs the amplified noise current. The current superimposition section 60 superimposes the noise current output from the random noise generator 40 on the driving current output from the laser driving circuit 30. The laser diode 11 is driven by the laser driving current on which the noise current is superimposed.

The operation of the thus configured laser source will be described. First, the operation of the optical system will be described.

The light emitted from the one end of the laser diode 11 is converted to collimating beam by the first lens 12, and then enters the diffraction grating 21. The light entering the diffraction grating 21 is diffracted by the diffraction grating 21, wavelength-dispersed to different angles depending on the wavelength, and then incident on the wavelength selecting mirror 22. Among the light incident on the wavelength selecting mirror 22, only the light of a desired wavelength is reflected to the diffraction grating 21 through the same optical path. The wavelength to be reflected through the same optical path is selected by the mirror rotating section 23.

The light incident on the diffraction grating 21 is again wavelength-dispersed. Only the light of the wavelength selected by the wavelength selecting section 20 is converged in the laser diode 11 by the first lens 12 to be fed back. The other end of the laser diode 11, and the wavelength selecting mirror 22 form an external cavity, and perform laser oscillation.

By contrast, the laser light emitted from the other end which is not provided with the antireflection coating 11a is converted to collimating beam by the second lens 13, and emitted as the output light. The wavelength selecting mirror 22 is rotated by the mirror rotating section 23, whereby the wavelength of the light fed back from the wavelength selecting section 20 to the optical amplifier 10 is made tunable, and a wavelength sweep of the output light is performed.

Then, the operations of the driving circuit 30 and the random noise generator 40 will be described. FIGS. 5A to 5C are views diagrammatically showing characteristics of the laser driving current, the noise current, and the spectral line width. As shown in FIG. 5A, the driving circuit 30 outputs the laser driving current (the current value: Id) for driving the laser diode, and, as shown in FIG. 5B, the random noise generator 40 supplies the noise current of a constant amplitude ΔI. The current superimposition section 60 superimposes the noise current on the laser driving current, and the resulting current is supplied to the laser diode 11. In FIGS. 5A and 5B, the abscissa indicates the time, and the ordinate indicates the current. In FIG. 5C, the abscissa indicates the wavelength “λ”, and the ordinate indicates the light intensity “P”.

As described in JP-A-10-107354, the variation of the laser driving current supplied to the laser diode 11, i.e., the variation of the injection current involves variations of the light intensity of the output light and electron density of the laser diode 11. The variation of the electron density involves the variation of the refractive index and the temperature variation, with the result that the frequency of the light is varied. Therefore, the laser diode 11 is driven by the laser driving current on which the noise current is superimposed, and as a result the output light of a wide spectral line width is obtained. As shown in FIG. 5C, namely, a spectrum 101 is obtained in which the spectral line width is wider than a spectrum 100 in the case where the noise current is not superimposed.

Also during a period when the wavelength sweep of the output light is performed by rotating the wavelength selecting mirror 22, the noise current is superimposed on the laser driving current, whereby the output light in which optical modulation is performed over the whole wavelength range, and in which the spectral line width is wide is output.

Japanese Patent No. 3,422,804 (paragraph [0014] to [0022], FIGS. 1 to 4) and JP-A-10-107354 (paragraph Nos. [0002] to [0005] and [0020] to [0031], FIGS. 1 and 2) are referred to as related art.

Even when the laser driving current is constant, usually, the light intensity of the output light of the laser diode 11 is varied depending on the wavelength. FIG. 6 shows an example of the wavelength characteristic of the laser diode 11. At a wavelength λmax, the light intensity of the output light is the maximum. In the vicinity of the wavelength λmax, the light intensity is flat, and, as advancing toward a shorter wavelength side and a longer wavelength side, the light intensity is rapidly attenuated. The specification of the spectral line width is defined at a predetermined wavelength, for example, the wavelength λmax, and a noise current satisfying the specification of the spectral line width is set. The specification of the spectral line width is set not over the whole wavelength range, but at the predetermined wavelength.

Conventionally, the specification is determined while the vicinity of the wavelength λmax is set as a tunable range. Recently, however, the tunable range is further widened by request of the user.

While the light intensity of the output light is varied depending on the wavelength, however, the amplitude ΔI of the noise current output from the random noise generator 40 is constant. Therefore, there arises a problem in that the laser oscillation is turned off at a wavelength where the laser oscillation threshold current is high. Specifically, as the light intensity is further reduced, the laser oscillation threshold current is higher, thereby producing a problem in that the laser oscillation is turned off and optical modulation cannot be performed.

### SUMMARY OF THE INVENTION

An object of the invention is to provide an external cavity type tunable laser source in which optical modulation can be performed irrespective of a light intensity of laser light.

The invention provides a external cavity type tunable laser source, having: a laser diode which cooperates with a reflecting section to constitute an external cavity, and outputs laser light; a laser driving circuit which supplies a laser driving current to the laser diode; a random noise generator which generates a noise current whose current value varies at random; an amplitude control section which controls an amplitude of the noise current output from the random noise generator based on a light intensity of the laser light output from the laser diode; and a current superimposition section which superimposes a noise current whose amplitude is controlled by the amplitude control section on the driving current output from the laser driving circuit.

In the external cavity type tunable laser source, the amplitude control section has: a storage section which stores a current value of the laser driving current and a light intensity of the laser light corresponding to the current value, for each wavelength of the laser light output from the laser diode; a calculating section which calculates an increasing/decreasing amount of an amplitude of the noise current based on a relationship between current values and light intensities stored in the storage section; and an amplitude adjusting section which attenuates or amplifies the amplitude of the noise current output from the random noise generator in accordance with a calculation result of the calculating section.

In the external cavity type tunable laser source, the amplitude control section has: a storage section which stores an increasing/decreasing amount of an amplitude of the noise current, for each wavelength of the laser light output from the laser diode; and an amplitude adjusting section which attenuates or amplifies the amplitude of the noise current output from the random noise generator in accordance with the increasing/decreasing amount stored in the storage section.

In the external cavity type tunable laser source, the amplitude control section has: a light receiving section which receives a part of the laser light output from the laser diode, to measure a light intensity; a calculating section which calculates an increasing/decreasing amount of an amplitude of the noise current based on the light intensity measured by the light receiving section; and an amplitude adjusting section which attenuates or amplifies the amplitude of the noise current output from the random noise generator in accordance with a calculation result of the calculating section.

According to the external cavity type tunable laser source, the amplitude control section controls (increases or decreases) the amplitude of the noise current output from the random noise generator on the basis of the light intensity of laser light. Therefore, the laser oscillation is not turned off, and the degree of modulation of the laser light can be set to a desired value. As a result, optical modulation can be performed irrespective of the light intensity of the laser light.

Furthermore, the light receiving section always measures the light intensity. Even when the current value of the laser driving current supplied from the laser driving circuit 30 is varied, therefore, the degree of modulation of the laser light can be set to the desired value. As a result, optical modulation can be performed irrespective of the light intensity of the laser light.

### BRIEF DESCRIPTION OF THE DRAWINGS

FIG. 1 is a diagram showing the configuration of a first embodiment of the invention;

FIG. 2 is a diagram showing the configuration of a second embodiment of the invention;

FIG. 3 is a diagram showing the configuration of a third embodiment of the invention;

FIG. 4 is a diagram showing the configuration of an external cavity type tunable laser source as a related art;

FIGS. 5A to 5C are views showing characteristics of a laser driving current, a noise current, and a spectral line width of laser light of a laser diode 11; and

FIG. 6 is a view showing relationships between the wavelength of laser light of the laser diode 11 and the light intensity.

### DETAILED DESCRIPTION OF THE PREFERRED EMBODIMENTS

Embodiments of the invention will be described with reference to the accompanying drawings.

### First Embodiment

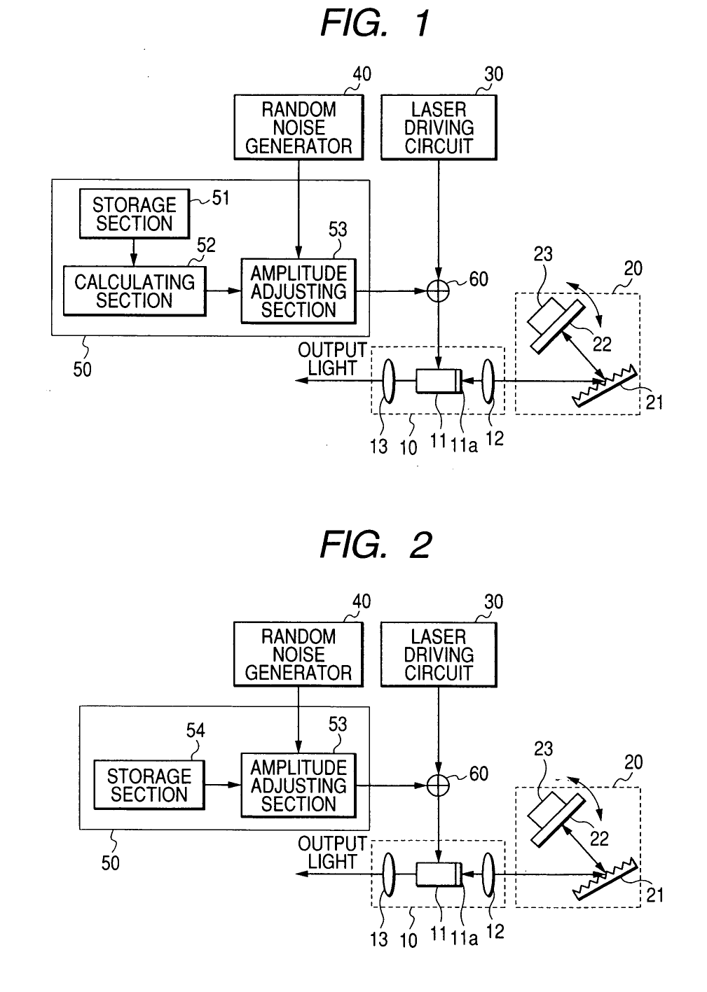

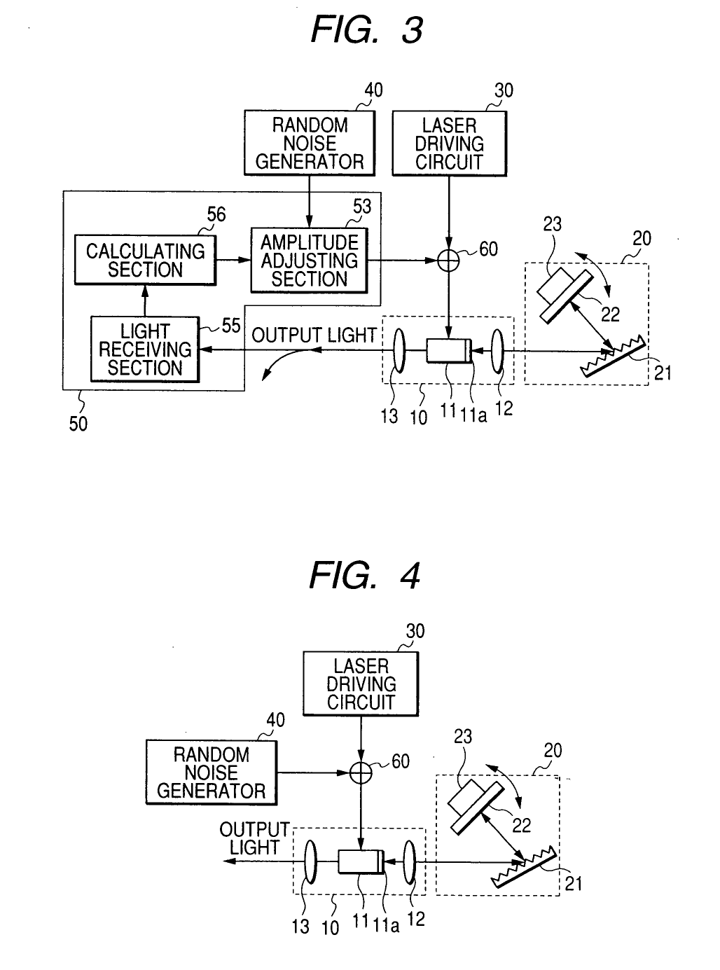

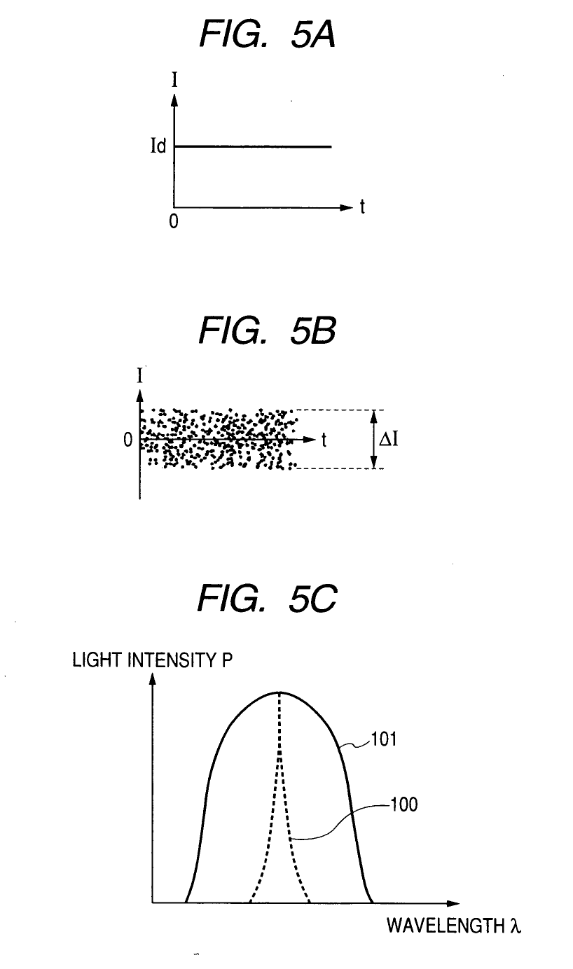

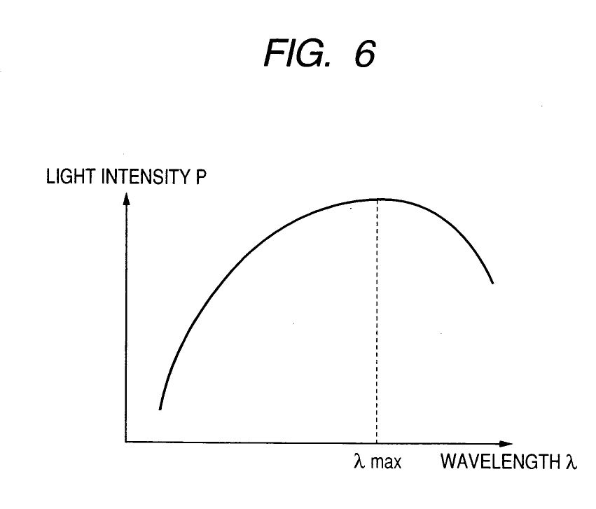

FIG. 1 is a diagram showing the configuration of a first embodiment of the invention. The components which are identical with those of FIG. 4 are denoted by the same reference numerals, and their description is omitted. Referring to FIG. 1, an amplitude control section 50 is newly disposed between the random noise generator 40 and the current superimposition section 60.

The amplitude control section 50 has a storage section 51, a calculating section 52, and an amplitude adjusting section 53. The amplitude control section 50 receives the noise current from the random noise generator 40 to attenuate or amplify the amplitude ΔI of the noise current on the basis of the light intensity of the laser light output from the laser diode 11. The resulting current is superimposed on the laser driving current in the current superimposition section 60.

The storage section 51 stores the current value of the laser driving current, and the light intensity of the laser light at the current value, for each wavelength of the laser light output from the laser diode 11. The calculating section 52 calculates an increasing/decreasing amount of the amplitude ΔI of the noise current from relationships of current values and light intensities stored in the storage section 51. The amplitude adjusting section 53 receives a calculation result from the calculating section 52, and the noise current from the random noise generator 40. In accordance with the calculation result, the amplitude adjusting section 53 attenuates or amplifies the amplitude ΔI of the noise current, and then outputs the noise current to the current superimposition section 60.

The operation of the thus configured laser source will be described.

Characteristics of the current value and the light intensity for each wavelength are stored in the storage section 51. Specifically, the laser driving circuit 30 outputs the laser driving current which has the constant current value Id irrespective of the wavelength of the output light. For each wavelength, for example, at the interval of 1 [nm], the light intensity of the output light of the laser diode 11 is measured. The relationship between the laser driving current and the light intensity for each wavelength is stored in the storage section 51.

Next, the current value Id is changed, and the relationship between the laser driving current and the light intensity for each wavelength is again stored in the storage section 51. This operation is repeated. Preferably, the storage into the storage section 51 may be conducted at adjustment before shipment of the laser source or at calibration of the laser source.

Then, the operation which is conducted in a usual state to perform the optical modulation to widen the spectral line width will be described.

The laser driving circuit 30 outputs the laser driving current of a constant level irrespective of the wavelength of the output light. On the other hand, the amplitude control section 50 obtains the current value Id of the laser driving current output from the laser driving circuit 30, and the wavelength selected by the wavelength selecting section 20. The calculating section 52 reads out the light intensity corresponding to the current value Id and the wavelength, from the storage section 51, and calculates the amplitude of a noise current at which the desired degree of modulation is attained, and obtains an increasing/decreasing amount.

Specifically, a ratio (i.e., an S/N ratio) of the light intensity of the output light of the laser diode 11 and an amplitude at which the light intensity is varied by the noise current, or namely an amplitude of a noise current which satisfies the specification of the spectral line width. Since the amplitude of the noise current which enables optical modulation within a range where the laser oscillation of the laser diode 11 is not turned off is calculated, the specification of the spectral line width is not always requested to be satisfied at a wavelength where the light intensity is low.

On the basis of the calculation result, the amplitude adjusting section 53 attenuates or amplifies the noise current of the random noise generator 40, and the noise current which is adjusted to a desired amplitude is superimposed on the laser driving current. The laser diode 11 is driven by the laser driving current on which the noise current is superimposed. The optical system operates in the same manner as the laser source shown in FIG. 4, and therefore its description is omitted.

As described above, the calculating section 52 calculates the amplitude of the noise current on the basis of the light intensity of the laser light which is read out from the storage section 51. In accordance with the calculation result, the amplitude adjusting section 53 increases or decreases the amplitude of the noise current output from the random noise generator 40. Therefore, the laser oscillation is not turned off, and the degree of modulation of the laser light can be set to a desired value. As a result, optical modulation can be surely performed irrespective of the light intensity of the laser light. Consequently, the spectral line width can be widened over the whole wavelength range.

In some cases, the laser driving current is varied, and, for example, the current value is reduced. When the noise current remains to have a constant amplitude, there is a case where the laser driving current flows from the laser diode 11 to the laser driving circuit 30, or in the direction (negative direction) opposite to the ordinary direction, and the laser diode 11 is reversely biased. As a result, there is a possibility that the laser diode 11 is broken. In the laser source shown in FIG. 1, however, the calculating section 52 calculates an increasing/decreasing amount of the amplitude of the noise current for each current value. Therefore, an excessive noise current is not superimposed on the laser driving current, and the laser diode is not broken.

### Second Embodiment

FIG. 2 is a diagram showing the configuration of a second embodiment of the invention. The components which are identical with those of FIG. 1 are denoted by the same reference numerals, and their description is omitted. Referring to FIG. 2, a storage section 54 is disposed in place of the storage section 51 and the calculating section 52. The storage section 54 stores an increasing/decreasing amount of the amplitude of the noise current, for each wavelength of the laser light output from the laser diode 11.

The operation of the thus configured laser source will be described.

First, an increasing/decreasing amount of the amplitude of the noise current for each wavelength is stored in the storage section 54. Specifically, the laser driving circuit 30 outputs the laser driving current which has the constant current value Id irrespective of the wavelength of the output light. For each wavelength, for example, at the interval of 1 [nm], the light-intensity of the output light of the laser diode 11 is measured. From the relationship between the laser driving current and the light intensity for each wavelength, an external apparatus such as a personal computer calculates an increasing/decreasing amount of the amplitude of the noise current, and the calculated increasing/decreasing amount is stored in the storage section 54.

Next, the current value Id is changed, and the relationship between the laser driving current and the light intensity for each wavelength is again stored in the storage section 54. This operation is repeated. Preferably, the storage into the storage section 54 may be conducted at adjustment before shipment of the laser source or at calibration of the laser source.

Then, the operation which is conducted in a usual state to widen the spectral line width. The operation is substantially identical with that of the laser source shown in FIG. 1, and the points of difference will be described. The amplitude adjusting section 53 reads out an increasing/decreasing amount corresponding to the current value Id and the wavelength, and attenuates or amplifies the noise current of the random noise generator 40, and the noise current which is adjusted to have a desired amplitude is superimposed on the laser driving current. The laser diode 11 is driven by the laser driving current on which the noise current is superimposed.

As described above, the amplitude of the noise current output from the random noise generator 40 is increased or decreased by the amplitude adjusting section 53 in accordance with the increasing/decreasing amount read out from the storage section 54. Therefore, the laser oscillation is not turned off, and the degree of modulation of the laser light can be set to a desired value. As a result, optical modulation can be surely performed irrespective of the light intensity of the laser light. Consequently, the spectral line width can be widened over the whole wavelength range.

In some cases, the laser driving current is varied, and, for example, the current value is reduced. When the noise current remains to have a constant amplitude, there is a case where the laser driving current flows from the laser diode 11 to the laser driving circuit 30, or in the direction (negative direction) opposite to the ordinary direction, and the laser diode 11 is reversely biased. As a result, there is a possibility that the laser diode 11 is broken. In the laser source shown in FIG. 2, however, the storage section 54 stores an increasing/decreasing amount of the amplitude of the noise current for each wavelength. Therefore, an excessive noise current is not superimposed on the laser driving current, and the laser diode is not broken.

### Third Embodiment

FIG. 3 is a diagram showing the configuration of a third embodiment of the invention. The components which are identical with those of FIG. 1 are denoted by the same reference numerals, and their description is omitted. Referring to FIG. 3, a light receiving section 55 and a calculating section 56 are disposed in place of the storage section 51 and the calculating section 52.

The light receiving section 55 receives part of the laser light output from the laser diode 11, and measures the light intensity. The calculating section 56 calculates an increasing/decreasing amount of the amplitude of the noise current in accordance with the light intensity supplied from the light receiving section 55.

The operation of the thus configured laser source will be described.

The laser driving circuit 30 outputs the laser driving current. The light output from the laser diode 11 is branched by a branch means such as an optical coupler or a half mirror, and one of branched light beams is supplied to the light receiving section 55. In the light receiving section 55, the input laser light is received by a photodiode, and a photocurrent which is proportional to the light intensity is output. The photocurrent is current-to-voltage converted by an IV converting circuit which is not shown, and further converted to a digital value by an AD converter which is not shown, to be output to the calculating section 56.

From the digital value which is supplied from the light receiving section 55 and proportional to the light intensity, the calculating section 56 calculates an increasing/decreasing amount of the amplitude of the noise current at this light intensity. On the basis of the calculation result, the amplitude adjusting section 53 attenuates or amplifies the noise current of the random noise generator 40, and the noise current which is adjusted to a desired amplitude is superimposed on the laser driving current. The laser diode 11 is driven by the laser driving current on which the noise current is superimposed. The optical system operates in the same manner as the laser source shown in FIG. 1, and therefore its description is omitted.

As described above, the light receiving section 55 measures the light intensity of the laser light, and the calculating section 56 calculates the amplitude of the noise current on the basis of the measurement result. In accordance with the calculation result, the amplitude adjusting section 53 increases or decreases the amplitude of the noise current output from the random noise generator 40. Therefore, the laser oscillation is not turned off, and the degree of modulation of the laser light can be set to a desired value. As a result, optical modulation can be surely performed irrespective of the light intensity of the laser light. Consequently, the spectral line width can be widened over the whole wavelength range.

In some cases, the laser driving current is varied, and, for example, the current value is reduced. When the noise current remains to have a constant amplitude, there is a case where the laser driving current flows from the laser diode 11 to the laser driving circuit 30, or in the direction (negative direction) opposite to the ordinary direction, and the laser diode 11 is reversely biased. As a result, there is a possibility that the laser diode 11 is broken. In the laser source shown in FIG. 3, however, the light receiving section 55 always measures the light intensity. Therefore, an excessive noise current is not superimposed on the laser driving current, and the laser diode is not broken.

The invention is not restricted to these embodiments, and may be configured in the following manner.

In the laser source shown in FIG. 1, the configuration in which the current value of the laser driving current is varied to several kinds, and the light intensity at each of the current values is stored in the storage section 51 has been described. In the case where the laser driving circuit 30 outputs a current value within a predetermined range, only a light intensity with respect to one current value may be stored, and the amplitude control section 50 may not obtain the current value of the laser driving current.

In the laser source shown in FIG. 2, the configuration in which the current value of the laser driving current is varied to several kinds, and the increasing/decreasing amount at each of the current values is stored in the storage section 54 has been described. In the case where the laser driving circuit 30 outputs a current value within a predetermined range, only an increasing/decreasing amount with respect to one current value may be stored, and the amplitude control section 50 may not obtain the current value of the laser driving current.

In the laser sources shown in FIGS. 1 and 2, the configuration in which the value is stored at the interval of 1 [nm] has been described. Any wavelength interval may be employed, and the interval may not be uniform.

In the laser sources shown in FIGS. 1 to 3, the configuration in which an external cavity type tunable laser source in a Littman arrangement is used has been described. The external cavity may have any configuration. For example, only a mirror serving as a reflecting means is disposed in the wavelength selecting section 20, and the mirror may be moved along the optical axis. Alternatively, only a diffraction grating serving as a reflecting means may be disposed in the wavelength selecting section, and the diffraction grating may be moved along the optical axis.

What is claimed is:

1. An external cavity type tunable laser source, comprising:
a laser diode which cooperates with a reflecting section to constitute an external cavity, and outputs laser light;
a laser driving circuit which supplies a laser driving current to the laser diode;
a random noise generator which generates a noise current whose current value varies at random; an amplitude control section which controls an amplitude of the noise current output from the random noise generator based on a light intensity of the laser light output from the laser diode; and
a current superimposition section which superimposes a noise current whose amplitude is controlled by the amplitude control section on the driving current output from the laser driving circuit.

2. The external cavity type tunable laser source according to claim 1,
wherein the amplitude control section has:
a storage section which stores a current value of the laser driving current and a light intensity of the laser light corresponding to the current value, for each wavelength of the laser light output from the laser diode;
a calculating section which calculates an increasing/decreasing amount of an amplitude of the noise current based on a relationship between current values and light intensities stored in the storage section; and
an amplitude adjusting section which attenuates or amplifies the amplitude of the noise current output from the random noise generator in accordance with a calculation result of the calculating section.

3. The external cavity type tunable laser source according to claim 1,
wherein the amplitude control section has:
a storage section which stores an increasing/decreasing amount of an amplitude of the noise current, for each wavelength of the laser light output from the laser diode; and
an amplitude adjusting section which attenuates or amplifies the amplitude of the noise current output from the random noise generator in accordance with the increasing/decreasing amount stored in the storage section.

4. The external cavity type tunable laser source according to claim 1,
wherein the amplitude control section has:
a light receiving section which receives a part of the laser light output from the laser diode, to measure a light intensity;
a calculating section which calculates an increasing/decreasing amount of an amplitude of the noise current based on the light intensity measured by the light receiving section; and
an amplitude adjusting section which attenuates or amplifies the amplitude of the noise current output from the random noise generator in accordance with a calculation result of the calculating section.
